(19) United States
(12) Patent Application Publication
(10) Pub. No.: US 2024/0038704 A1
(43) Pub. Date: Feb. 1, 2024

(54) HYBRID SEMICONDUCTOR DEVICE ASSEMBLY INTERCONNECTION PILLARS AND ASSOCIATED METHODS

(71) Applicant: Micron Technology, Inc., Boise, ID (US)

(72) Inventors: Faxing Che, Singapore (SG); Hong Wan Ng, Singapore (SG); Yeow Chon Ong, Singapore (SG)

(21) Appl. No.: 17/874,206

(22) Filed: Jul. 26, 2022

(51) Int. Cl. H01L 23/00

(52) U.S. Cl. CPC H01L 24/13; H01L 24/16; H01L 24/11; H01L 24/81; H01L 2224/81815; H01L 2224/81203; H01L 2924/37001; H01L 2924/3512; H01L 2224/16148; H01L 2224/16221; H01L 2224/11462; H01L 2224/13007; H01L 2224/13014; H01L 2224/13017; H01L 2224/13019; H01L 2224/13076; H01L 2224/13147; H01L 2224/13541; H01L 2224/1355; H01L 2224/13655; H01L 2224/1369; H01L 2224/13582

(57) ABSTRACT

In some embodiments, a semiconductor device assembly can include a first semiconductor die, a second semiconductor die, and an interconnection structure therebetween. The interconnection structure can directly electrically couple the first and the second semiconductor dies. The interconnection structure can include an inner metallic pillar, an outer metallic shell, a continuous metallic bridging layer, and a dielectric liner. The outer metallic shell can surround and be spaced from the inner metallic pillar, the continuous metallic bridging layer can be over and connected with the inner metallic pillar and the outer metallic shell, and the dielectric liner can be between the inner metallic pillar and the outer metallic shell. In some embodiments, the second semiconductor die can be excluded and the interconnection structure can solely be coupled to the first semiconductor die.

### TECHNICAL FIELD

The present disclosure is generally related to semiconductor device assembly interconnection structures. In particular, the present technology relates to hybrid semiconductor device interconnection pillars.

### BACKGROUND

Microelectronic devices, such as memory devices and microprocessors, and other electronics typically include one or more semiconductor devices and/or components attached to a substrate and/or another semiconductor device and/or component, and encased in a protective covering. The devices and/or components include at least one functional feature, such as memory cells, processor circuits, and/or interconnecting circuitry, etc. Each device and/or component commonly includes an array of small bond pads electrically coupled to the functional features therein for interconnection with other devices and/or components.

In some applications, these bond pads interconnect with other device and/or components using metallic interconnection pillars, such as copper pillars. These pillars provide both a physical and an electrical coupling between the device and/or components they connect. Because manufacturers are under increasing pressure to reduce the space occupied by assemblies including these devices and components, while simultaneously increasing the capacity and/or speed of operation, interconnection pillars must be increasingly small and still provide sufficient physical strength and current carrying capacity. Small interconnection pillars are susceptible to cracking or joint failure, such as separating from the components they are attached to or interconnecting when experiencing stress from component mismatch and/or thermal cycling, leading to faulty and/or non-operational devices, components, or assemblies thereof.

### BRIEF DESCRIPTION OF THE DRAWINGS

FIG. 1A is a side cross sectional view of a semiconductor device assembly having a hybrid interconnection pillar, configured in accordance with some embodiments of the present technology.

FIG. 1B is a top cross sectional view of the semiconductor device assembly of FIG. 1A, configured in accordance with some embodiments of the present technology.

FIGS. 2-8 illustrate a process for producing a hybrid interconnection pillar, in accordance with some embodiments of the present technology.

FIG. 9 is a flow diagram illustrating a process for producing a hybrid interconnection pillar, in accordance with some embodiments of the present technology.

FIG. 10 is a schematic diagram illustrating a semiconductor device assembly incorporating the present technology, configured in accordance with some embodiments of the present technology.

The drawings have not necessarily been drawn to scale. Similarly, some components or operations can be separated into different components or combined into a single assembly for the purpose of discussion of some of the implementations of the present technology. Moreover, while the technology is amenable to various modifications and alternative forms, specific implementations have been shown by way of example in the drawings and are described in detail below.

### DETAILED DESCRIPTION

The devices and methods of the present technology relate to semiconductor device assemblies with hybrid interconnection pillars (e.g., structures) for improving interconnection integrity and device/assembly reliability. The interconnection pillars can be hybrid because the pillars include multiple material compositions arranged according to some embodiments herein. For example, the hybrid interconnection pillars can include a conductive (e.g., metallic) outer annular column and a conductive central cylinder connected by a bridging layer; and a nonconductive (e.g., dielectric, polymer) inner annular column between the outer annular column and the central pillar, and under the bridging layer. By including multiple materials within the hybrid interconnection pillar, the hybrid interconnection pillar can have greater flexibility versus traditional metallic pillars and greater conductivity versus dielectric core pillars. Further, aspects of hybrid interconnection pillars with greater flexibility and conductivity provide many additional benefits including, for example: (i) reduced stress within semiconductor devices (e.g., within Cu/low-K BEOL layers of semiconductor devices) and device failure therefrom caused by, for example, device CTE (coefficient of thermal expansion) mismatch, temperature cycling, and/or deformation, (ii) reduced instances of pillar interconnection failure (e.g., cracking, separation, joint fatigue) caused by device mismatch, temperature cycling, and/or deformation, (iii) increased device yield given the above improvements, and (iv) decreased material costs because metallic portions of the interconnection pillars are replaced with a less costly polymer or other dielectric material.

In some embodiments, a semiconductor device assembly can include a first semiconductor die, a second semiconductor die, and an interconnection structure therebetween. The interconnection structure can directly electrically couple the first and the second semiconductor dies. The interconnection structure can include an inner metallic pillar, an outer metallic shell, a continuous metallic bridging layer, and a dielectric liner. The outer metallic shell can surround and be spaced from the inner metallic pillar, the continuous metallic bridging layer can be over and connect the inner metallic pillar and the outer metallic shell, and the dielectric liner can be between the inner metallic pillar and the outer metallic shell. In some embodiments, the second semiconductor die can be excluded and the interconnection structure can solely be coupled to the first semiconductor die.

The interconnection structure can be formed on the first semiconductor die by first preparing a semiconductor die with a bond pad on a top surface thereof. A dielectric layer can be formed over the bond pad and the top surface, and a portion of the dielectric layer removed to form an annular dielectric liner on the bond pad. A metallic seed layer can be formed over the bond pad, the top surface, and the dielectric liner. A photoresist layer can be formed over the metallic seed layer, leaving an opening over the bond pad and surrounding the dielectric liner. The interconnection structure can be formed by plating a metal into the opening. The interconnection pillar can include a pillar in a central space of the annular dielectric liner, a shell surrounding an outer surface of the annular dielectric liner, and a bridging layer over the pillar, the shell, and the annular dielectric liner. The patterned photoresist layer and the metallic seed layer can then be removed from the top surface and the bond pad surrounding the interconnect structure.

For ease of reference, the semiconductor device and other components are sometimes described herein with reference to top, bottom, left, right, and/or above/over relative to the spatial orientation of the embodiments shown in the figures. It is to be understood, however, that the semiconductor devices and the modifications therein can be moved to, and used in, different spatial orientations without changing the structure and/or function of the disclosed embodiments of the present technology.

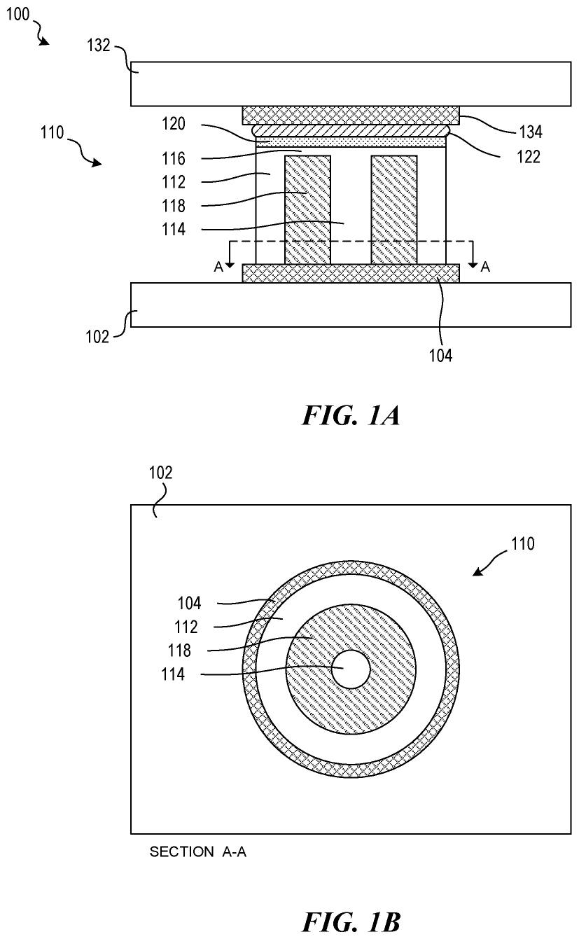

FIGS. 1A and 1B illustrate a semiconductor device assembly 100 having a hybrid interconnection pillar 110, configured in accordance with some embodiments of the present technology. FIG. 1A is a side cross sectional view of the assembly 100 and the hybrid interconnection pillar 110, and FIG. 1B is a top cross sectional view of the assembly 100 and the hybrid interconnection pillar 110. As shown in FIG. 1A, the assembly 100 can include a first device 102 (e.g., a first semiconductor die) and a second device 132 (e.g., a second semiconductor die, or substrate) physically and electrically coupled by the hybrid interconnection pillar 110 bonded to and extending between a bond pad 104 of the first device and a bond pad 134 of the second device 132. The first device 102 and the second device 132 can each individually be a memory and/or a processing device, such as a memory die, a graphics processing unit, a logic device, or any similar semiconductor device including a semiconductor substrate. The hybrid interconnection pillar 110 can electrically connect components on or within the semiconductor substrates of the first device 102 and the second device 132, respectively, via the bond between the hybrid interconnection pillar 110 and the bond pad 104 of the first device 102 and the bond pad 134 of the second device 132. Further, in some embodiments, the first device 102 and the second device 132 can include additional hybrid interconnection pillars 110 therebetween.

By including hybrid interconnection pillar 110 between the first device 102 and the second device 132, the physical coupling between the devices 102, 132 will have greater flexibility versus traditional metallic pillars and greater conductivity versus dielectric core pillars. Further, when the assembly 100 includes a more flexible interconnect between the devices 102, 132, the assembly benefits from, for example: (i) reduced stress within semiconductor devices (e.g., up to 50% or more stress reduction within the devices at the interconnection pillar) and device failure therefrom caused by, for example, device mismatch, temperature cycling, and/or deformation, (ii) reduced instances of pillar interconnection failure (e.g., up to 60% or more increased joint reliability) caused by device mismatch, temperature cycling, and/or deformation, (iii) increased device yield given the above improvements, and (iv) decreased material costs because metallic portions of the interconnection pillars are replaced with a less costly polymer or similar dielectric material.

Referencing both FIGS. 1A and 1B, the hybrid interconnection pillar 110 can include a conductive structure having an outer shell 112 and an inner pillar 114 connected by a bridging layer 116, a nonconductive structure having a dielectric liner 118 between the outer shell 112 and the inner pillar 114, a metallic interconnection layer 120 over the bridging layer 116, and a solder bond 122 over the metallic interconnection layer 120. The outer shell 112 and the dielectric liner 118 can each include an annular column extending from the bond pad 104 of the first device 102, and the inner pillar 114 can include a cylinder extending from the bond pad 104 of the first device 102. The outer shell 112 and the dielectric liner 118 can be concentric with the inner pillar 114, and/or the outer shell 112, the dielectric liner 118, and/or the inner pillar 114 can be concentric with the bond pad 104 of the first device 102. The outer shell 112 can surround the dielectric liner 118 and the inner pillar 114, and the dielectric liner 118 can surround the inner pillar 114. An inner surface of the outer shell 112 can be coincident with an outer surface of the dielectric liner 118, and an inner surface of the dielectric liner 118 can be coincident with an exterior surface of the inner pillar 114.

The bridging layer 116 can cover the outer shell 112, the inner pillar 114, and the dielectric liner 118, and can electrically couple the outer shell 112 and the inner pillar 114. As illustrated in FIG. 1A, the outer shell 112 and the inner pillar 114 can have corresponding heights (e.g., the distance from the bond pad 104 to a top of the outer shell 112 and the inner pillar 114 is the same) and the bridging layer 116 can correspond with a disk-like shape parallel or non-parallel with the bond pad 104. In some embodiments, the outer shell 112 and the inner pillar 114 can vary in height (e.g., the outer shell 112 or the inner pillar 114 can be taller) and the bridging layer 116 can correspond with a flanged frustum (e.g., bowl-like) shape. The metallic interconnection layer 120 can cover the bridging layer 116, and the solder bond 122 can cover the metallic interconnection layer 120. The components on and/or within the second device 132 can be electrically coupled to the components on and/or within the first device 102 via the bond pad 134 of the second device 132, the solder bond 122, the metallic interconnection layer 120, the conductive structure, and the bond pad 104 of the first device 102. In some embodiments, the metallic interconnection layer 120 can be excluded or combine with the bridging layer 116 or the solder bond 122.

In some embodiments, the hybrid interconnection pillar 110 can include additional conductive and/or non-conductive annular structures extending from the bond pad 104 of the first device 102 and surrounding the outer shell 112, the dielectric liner 118, and the inner pillar 114. For example, the hybrid interconnection pillar 110 can include an additional dielectric annular column radially exterior to the outer shell 112. As a further example, the hybrid interconnection pillar 110 can include an additional dielectric annular column radially exterior to the outer shell 112 and an additional conductive annular column radially exterior to the additional dielectric annular column. In some embodiments, the hybrid interconnection pillar 110 can include two or more (e.g., 3, 4, 5) additional dielectric annular columns and one or more additional (e.g., 2, 3, 4) conductive annular columns surrounding the outer shell 112, the dielectric liner 118, and the inner pillar 114. When the hybrid interconnection pillar 110 includes additional conductive and/or non-conductive annular structures, the bridging layer 116, the metallic interconnection layer 120, and the solder bond 122 can further radially extend over the additional conductive and/or non-conductive annular structures.

Although as illustrated in FIG. 1B, the outer shell 112, the dielectric liner 118, and the inner pillar 114 have circular exterior cross sectional perimeters (e.g., a shape of an exterior surface of the annular or cylindrical column), in some embodiments, the outer shell 112, the dielectric liner 118, and/or the inner pillar 114 can have a non-circular exterior cross sectional exterior. For example, the outer shell 112, the dielectric liner 118, and/or the inner pillar 114 can have an ovular or other, similarly rounded exterior cross sectional perimeter. Further, in some embodiments, the outer shell 112 and/or the dielectric liner 118 can have a non-circular interior cross sectional perimeter (e.g., a shape of an inner surface of the annular column) corresponding with the exterior cross sectional perimeter of the dielectric liner 118 or the inner pillar 114, respectively.

The outer shell 112, the inner pillar 114, the bridging layer 116, and the metallic interconnection layer 120 can include any suitable conductive material such as, for example, copper, gold, silver, aluminum, tungsten, cobalt, nickel, or any other suitable conductive material or combination thereof. In some embodiments, two or more of the outer shell 112, the inner pillar 114, the bridging layer 116, or the metallic interconnection layer 120 can include the same material. The solder bond 122 can include any suitable solder material. The dielectric liner 118 can include any suitable dielectric, nonconductive material such as, for example, a polymer or other suitable dielectric, nonconductive material with a greater flexibility than the material of the outer shell 112 and the inner pillar 114.

Although not shown in FIGS. 1A and 1B, in some embodiments, the first device 102 can include one or more metallization layers (e.g., BOEL (or portions thereof), titanium, copper, etc.) over a top surface of the first device and/or over a portion of the bond pad 104 of the first device 102. In these embodiments, a portion of one or more metallization layers can be between the outer shell 112, the dielectric liner 118, and/or the inner pillar 114 and the bond pad 104. Further, a portion of one or more metallization layers can cover a portion of an exterior surface of the outer shell 112. For example, a portion of a BOEL layer, a portion of a titanium layer, and a portion of a copper layer can be between the outer shell 112 and the bond pad 104. As a further example, the titanium layer and the copper layer can further be between both the dielectric liner 118 and the inner pillar 114 and the bond pad 104.

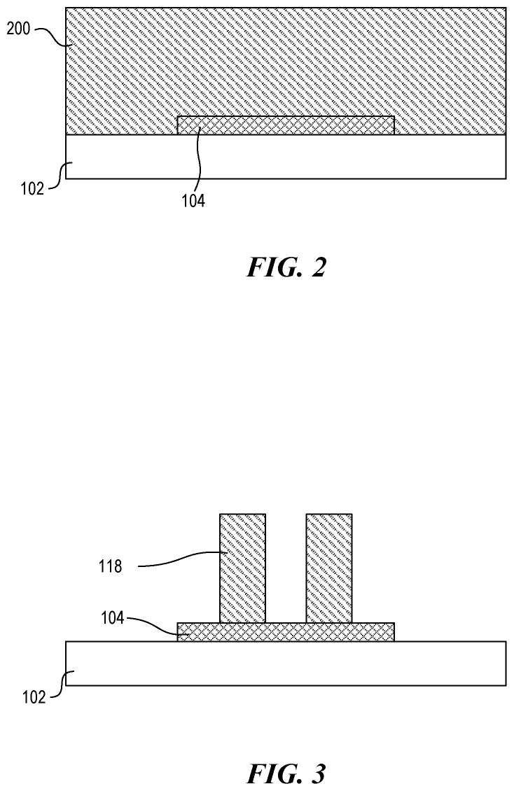

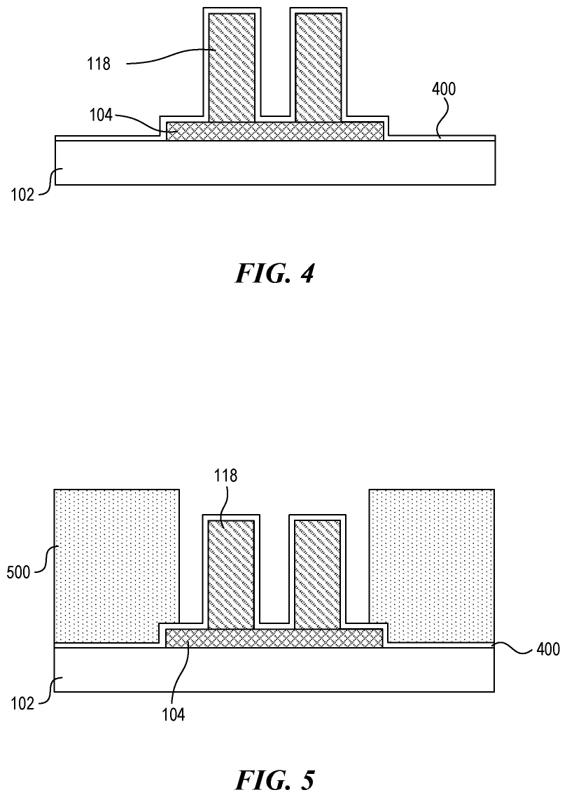

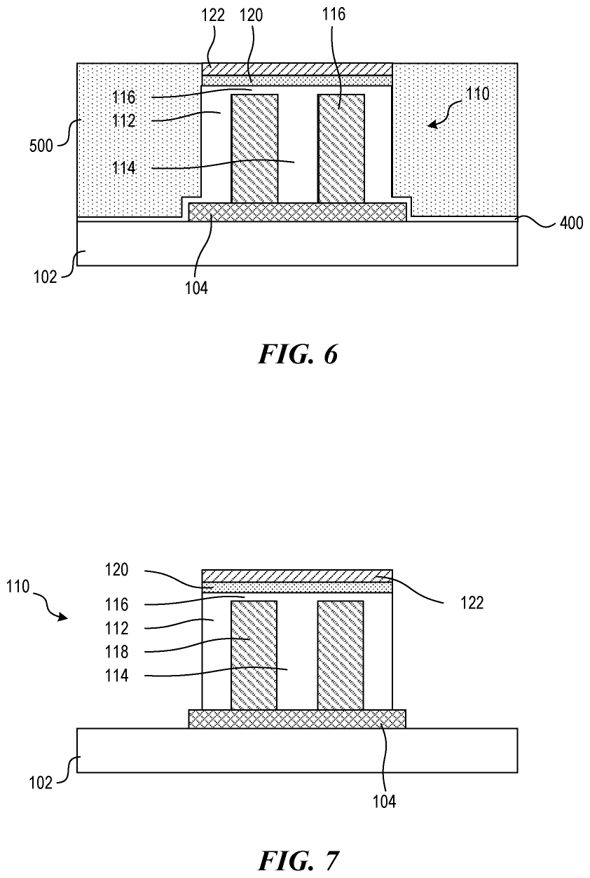

FIGS. 2-9 illustrate a process for producing at least the hybrid interconnection pillar of FIGS. 1A and 1B, in accordance with some embodiments of the present technology. The process can generally include: (i) forming a nonconductive layer 200 (FIG. 2), (ii) etching the nonconductive layer to form the dielectric liner 118 (FIG. 3), (iii) forming a metallic seed layer 400 (FIG. 4), (iv) forming a patterned photoresist layer 500 (FIG. 5), (v) forming the conductive structure, the metallic interconnection layer 120, and the solder bond 122 (FIG. 6), (vi) removing the patterned photoresist layer 500 and portions of the metallic seed layer 400 (FIG. 7), and (vii) bonding the second device 132 to the first device 102 at the hybrid interconnection pillar 110.

FIG. 2 illustrates a side cross sectional view of the first device 102 and the bond pad 104 of the first device 102 after forming a nonconductive layer 200 over the top surfaces thereof. The nonconductive layer 200 can be bonded to the top surface of the first device 102 and the bond pad 104 and can have a height from the top surface of the bond pad 104 to a top surface of the nonconductive layer 200 equal to or greater than a height of the to-be formed dielectric liner 118 (FIG. 3).

FIG. 3 illustrates a side cross sectional view of the first device 102 with the dielectric liner 118 formed on the bond pad 104. As shown, the dielectric liner 118 is a nonconductive annular column extending from the top surface of the bond pad 104. The dielectric liner 118 can be formed by thinning and etching the nonconductive layer 200 to re-expose the top surfaces of the first device 102 and the bond pad 104, except for the annular column above the bond pad 104 corresponding with the dielectric liner 118.

FIG. 4 illustrates a side cross sectional view of the first device 102 after the metallic seed layer 400 is formed over the first device 102, the bond pad 104, and the dielectric liner 118. As shown, the metallic seed layer 400 is a layer of material over the exposed surfaces (e.g., the top and/or side surfaces) of the first device 102, the bond pad 104, and the dielectric liner 118. The metallic seed layer 400 can be formed using an additive process including, for example, sputtering, physical vapor deposition (PVD), electroplating, lithography, or any other similar process. The metallic seed layer 400 can include suitable metallic material for seeding later formation of the outer shell 112, the inner pillar 114, and the bridging layer 116 therefrom (FIG. 6). For example, the metallic seed layer 400 can include copper, gold, silver, aluminum, tungsten, cobalt, nickel, or any other suitable metallic material.

FIG. 5 illustrates a side cross sectional view of the first device 102 after the patterned photoresist layer 500 is formed over the metallic seed layer 400 above the first device 102 and the bond pad 104. As shown, the photoresist layer 500 is patterned to provide an opening surrounding the dielectric liner 118 above the bond pad 104. The opening can include portions for forming the outer shell 112 (e.g., an outer annular opening portion); the inner pillar 114 (e.g., an inner pillar opening portion); and the bridging layer 116, the metallic interconnection layer 120, and the solder bond 122 (e.g., an upper cylindrical opening portion) from the metallic seed layer 400. The photoresist layer 500 can be formed using any suitable additive manufacturing process including, for example, a coating or other similar process. The opening can be maintained by selectively stopping photoresist layer 500 formation surrounding the dielectric liner 118. Alternatively, the opening can be formed by applying the photoresist layer 500 over the metallic seed layer 400 above the first device 102, the bond pad 104, and the dielectric liner 118, and then selectively etching portions of the photoresist layer 500 from above the bond pad 104 and the dielectric liner 118.

FIG. 6 illustrates a side cross sectional view of the first device 102 after forming the hybrid interconnection pillar 110 within the opening. As shown, the outer shell 112, the inner pillar 114, and the bridging layer 116 extend from the metallic seed layer 400; the metallic interconnection layer 120 extends from the bridging layer 116; and the solder bond 122 extends from the metallic interconnection layer 120. The outer shell 112, the inner pillar 114, the bridging layer 116, the metallic interconnection layer 120, and the solder bond 122 can be formed using an additive manufacturing process including, for example, plating, depositing, or any other similar suitable method. The outer shell 112, the inner pillar 114, and the bridging layer 116 can be formed from the metallic seed layer 400 to fill the outer annular opening portion, the inner pillar opening portion, and a lower part of the upper cylindrical opening portion above the bond pad 104. The metallic interconnection layer 120 and the solder bond 122 can be formed to fill the remainder (e.g., an upper part) of the upper cylindrical opening portion.

FIG. 7 illustrates a side cross sectional view of the first device 102 after removing the patterned photoresist layer 500 and portions of the metallic seed layer 400 thereunder. As shown, the first device 102 and the bond pad 104 are free of the photoresist layer 500 (FIG. 6) above the top surface of the first device 102 and an exterior portion of the top surface of the bond pad 104, leaving the completed hybrid interconnection pillar 110 above the bond pad 104. The photoresist layer 500 can be removed by etching above the first device 102 and the bond pad 104 to re-expose the top surfaces thereof.

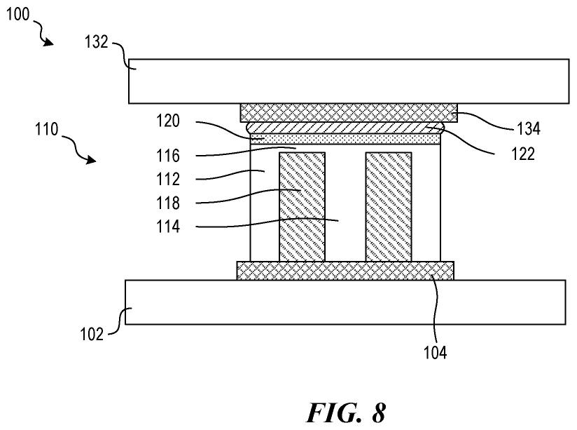

FIG. 8 illustrates a side cross sectional view of the assembly 100 after the second device 132 is bonded to the first device 102 at the hybrid interconnection pillar 110. As shown, the bond pad 134 of the second device 132 is vertically aligned with the hybrid interconnection pillar 110 and the bond pad of the first device 102, and the hybrid interconnection pillar 110 physically and electrically couples the first device 102 and the second device 132 together. The second device 132 can be bonded to the first device 102 by placing the bond pad 134 of the second device 132 vertically adjacent to the solder bond 122 during a reflow operation. For example, the first device 102 and the hybrid interconnection pillar 110 can be heated to reflow (e.g., at least partially liquify) the solder bond 122 and adhere the solder bond 122 between the bond pad 134 of the second device 132 and the metallic interconnection layer 120. In some embodiments, a compression force can be applied to press the first device 102 and the second device 132 together during the reflow operation and/or TCB (thermal compression bonding) process.

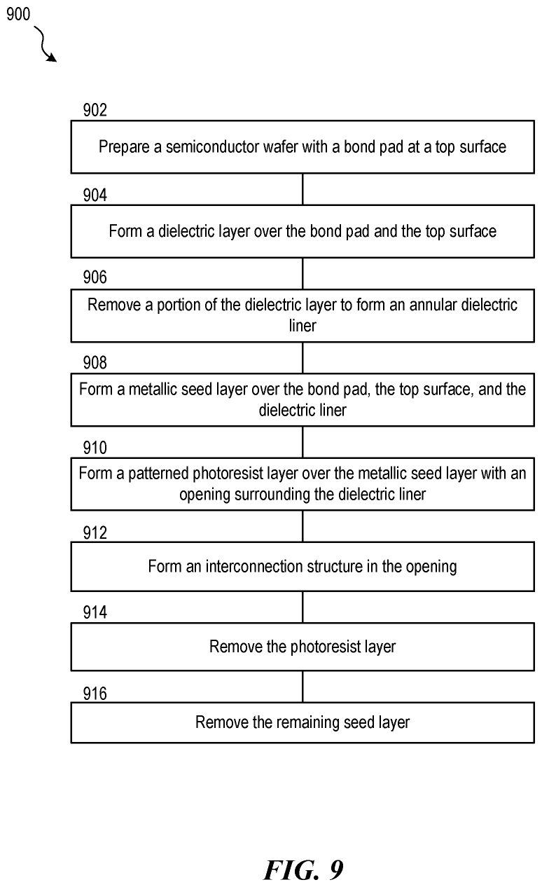

FIG. 9 is a flow diagram illustrating a process 900 for producing at least the hybrid interconnection pillar 110 of FIGS. 1A and 1B, in accordance with some embodiments of the present technology. The operations of process 900 are intended for illustrative purposes and are non-limiting. In some embodiments, for example, the process 900 can be accomplished with one or more additional operations not described, without one or more of the operations described, or with operations described and/or not described in an alternative order. As shown in FIG. 9, the process may include: preparing a semiconductor wafer with a bond pad at a top surface (process portion 902), forming a dielectric layer over the bond pad and the top surface (process portion 904), removing a portion of the dielectric layer to form an annular dielectric liner (process portion 906), forming a metallic seed layer over the bond pad, the top surface, and the dielectric layer (process portion 908), forming a patterned photoresist layer over the metallic seed layer with an opening surrounding the dielectric liner (process portion 910), forming an interconnection structure in the opening (process portion 912), removing the photoresist layer (process portion 914), and removing the remaining seed layer (process portion 916).

Preparing the semiconductor wafer with the bond pad at the top surface (process portion 902) can include using an additive process, including, for example, sputtering, PVD, electroplating, lithography, or other similar process to form a semiconductor substrate. The bond pad can then be formed using an additive process, including, for example, plating, depositing, or any other suitable process for forming the bond pad on the top surface of the semiconductor substrate. Forming the dielectric layer over the bond pad and the top surface (process portion 904) can similarly include using an additive process, such as a coating process or other similar process.

Removing the portion of the dielectric layer to form the annular dielectric liner (process portion 906) can include using an etching or cutting operation to selectively remove and/or thin the dielectric layer over, and to re-expose, the bond pad and the top surface, leaving an annular column of the dielectric layer (e.g., the dielectric liner) over the bond pad. In embodiments where the hybrid interconnection structure includes multiple dielectric liners, removing a portion of the dielectric layer can include leaving multiple, concentric annular columns of the dielectric layer over the bond pad.

Forming the metallic seed layer over the bond pad, the top surface, and the dielectric liner (process portion 908) can include using an additive process, the same or similar to one or more of those used to form the bond pad in process portion 902, to form a layer of metal over the bond pad, the top surface, and the dielectric liner.

Forming the patterned photoresist layer over the metallic seed layer with the opening surrounding the dielectric liner (process portion 910) can include using an additive process, the same or similar to one or more of those used to form the bond pad in process portion 902, to form the photoresist layer over the metallic seed layer above the top surface of the semiconductor substrate and over an exterior portion of the top of the bond pad. The photoresist layer can be patterned to leave an opening surrounding and spaced from the dielectric liner, leaving the metallic seed layer over an inner portion of the top of the bond pad, and over the dielectric liner, exposed.

Forming the interconnection structure in the opening (process portion 912) can include using an additive process, the same or similar to one or more of those used to form the bond pad in process portion 902, to form an outer conductive shell, an inner conductive pillar, a conductive bridging layer, a metallic interconnection layer, and a solder bond in the opening. The outer conductive shell can be formed between the dielectric liner and an inner surface of the photoresist layer from the metallic seed layer to a top of the dielectric liner. The inner conductive pillar can be formed within the dielectric liner from the metallic seed layer to the top of the dielectric liner. The conductive bridging layer can be formed over a top of the outer conductive shell, a top of the inner conductive pillar, and the top of the dielectric liner; and can electrically couple the outer conductive shell and the inner conductive pillar. The metallic interconnection layer can be formed over the bridging layer, and the solder bond can be formed over the metallic interconnection layer.

Removing the photoresist layer (process portion 914) and removing the remaining metallic seed layer (process portion 916) can include using an etching or cutting operation to selectively remove the photoresist layer and the metallic seed layer above the top surface of the semiconductor substrate and the exterior portion of the top of the bond pad, re-exposing the semiconductor substrate and the bond pad, and leaving the completed hybrid interconnection structure above the bond pad.

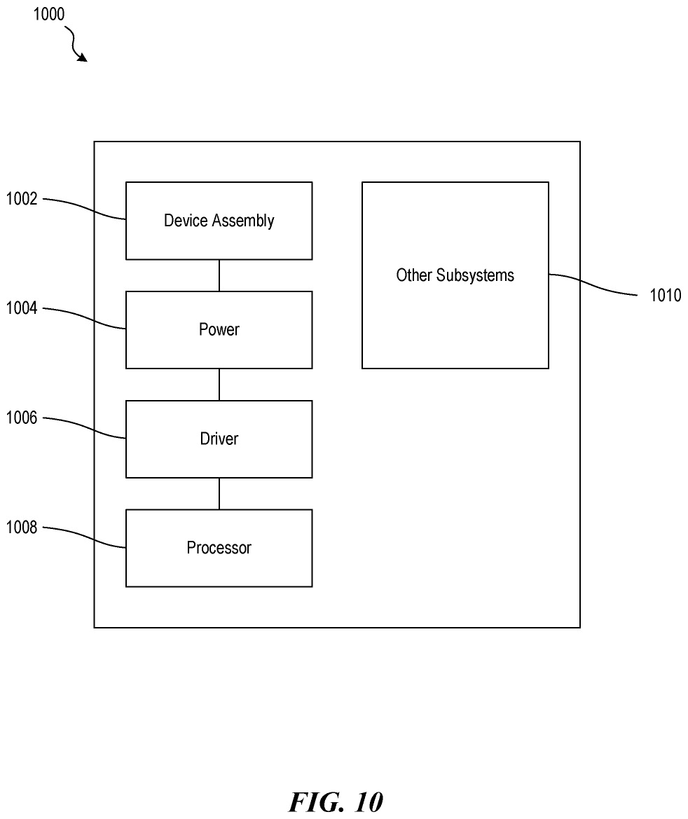

Any one of the semiconductor devices and/or semiconductor device assemblies described above with reference to FIGS. 1-9 can be incorporated into any of a myriad of larger and/or more complex systems, a representative example of which is system 1000 shown schematically in FIG. 10. The system 1000 can include a semiconductor device assembly 1002 (e.g., the assembly 100 of FIG. 1), a power source 1004, a driver 1006, a processor 1008, and/or other subsystems or components 1010. The semiconductor device assembly 1002 can include features generally similar to those of the semiconductor devices and assemblies described above with reference to FIGS. 1-9. The resulting system 1000 can perform any of a wide variety of functions, such as memory storage, data processing, or other suitable functions. Accordingly, representative systems 1000 can include, without limitation, hand-held devices (e.g., mobile phones, tablets, digital readers, and digital audio players), computers, vehicles, appliances and other products. Components of the system 1000 may be housed in a single unit or distributed over multiple, interconnected units (e.g., through a communications network). The components of the system 1000 can also include remote devices and any of a wide variety of computer readable media.

Further, systems 1000 incorporating the semiconductor devices and/or semiconductor device assemblies described above with reference to FIGS. 1-9 can similarly benefit from the hybrid interconnection structures (e.g., hybrid interconnection pillar 110 of FIGS. 1A and 1B) therein. For example, by including hybrid interconnection structures with greater flexibility versus traditional metallic structures and greater conductivity versus dielectric core structures, the systems 1000 benefits from, for example: (i) reduced stress between semiconductor devices therein (e.g., up to 50% or more stress reduction within the devices at the interconnection structure) and device failure therefrom caused by, for example, device mismatch, temperature cycling, and/or deformation, (ii) reduced instances of structure interconnection failure between semiconductor devices therein (e.g., up to 60% or more increased joint reliability) caused by device mismatch, temperature cycling, and/or deformation, (iii) increased system 1000 yield given the above improvements, and (iv) decreased material costs because metallic portions of the interconnection structures are replaced with a less costly polymer or similar dielectric material.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Additionally, the terms “comprising,” “including,” “having,” and “with” are used throughout to mean including at least the recited feature(s) such that any greater number of the same features and/or additional types of other features are not precluded. As used herein, the term “and/or,” as in a list of A, B, and/or C, refers to A or B or C; AB or AC or BC; or ABC (i.e., A and B and C).

As used herein, the terms “vertical,” “lateral,” “upper,” “lower,” “above,” and “below” can refer to relative directions or positions of features in the semiconductor devices in view of the orientation shown in the Figures. For example, “top” or “upper” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation. It should be noted that the methods described above describe possible implementations, and that the operations and the steps may be rearranged or otherwise modified and that other implementations are possible. Furthermore, embodiments from two or more of the methods may be combined.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A semiconductor device assembly comprising:
a first semiconductor die;
a second semiconductor die; and
an interconnection structure directly electrically coupling the first and the second semiconductor dies, the interconnection structure including:
an inner metallic pillar,
an outer metallic shell surrounding and spaced from the inner metallic pillar,
a continuous metallic bridging layer over and connected with the inner metallic pillar and the outer metallic shell, and
a dielectric liner between the inner metallic pillar and the outer metallic shell.

2. The semiconductor device assembly of claim 1, wherein the interconnection structure is formed on a first bond pad of the first semiconductor die.

3. The semiconductor device assembly of claim 1, wherein the continuous metallic bridging layer carries a solder material.

4. The semiconductor device assembly of claim 3, wherein the solder material physically and electrically couples the second semiconductor die to the interconnection structure.

5. The semiconductor device assembly of claim 1, wherein the inner metallic pillar, the outer metallic shell, and the continuous metallic bridging layer are a monolithic metallic material.

6. The semiconductor device assembly of claim 1, wherein the inner metallic pillar has a cylindrical shape, wherein the outer metallic shell has an annular column shape, and wherein the dielectric liner has an annular column shape.

7. The semiconductor device assembly of claim 6, wherein an exterior surface of the dielectric liner is coincident with an interior surface of the outer metallic shell.

8. The semiconductor device assembly of claim 6, wherein an exterior surface of the inner metallic pillar is coincident with an interior surface of the dielectric liner.

9. A semiconductor device comprising:
a semiconductor substrate; and
an interconnection structure electrically coupled to the semiconductor substrate, the interconnection structure including:
an inner metallic pillar,
an outer metallic shell surrounding and spaced from the inner metallic pillar,
a continuous metallic bridging layer over and connected with the inner metallic pillar and the outer metallic shell, and
a dielectric liner between the inner metallic pillar and the outer metallic shell.

10. The semiconductor device of claim 9, wherein the outer metallic shell is a first outer metallic shell and the dielectric liner is a first dielectric liner, and wherein the interconnection structure further includes:
a second outer metallic shell surrounding and spaced from the first outer metallic shell, and
a second dielectric liner between the first outer metallic shell and the second outer metallic shell, and wherein the continuous metallic bridging layer is further over and connected with the second outer metallic shell.

11. The semiconductor device of claim 9, wherein the inner metallic pillar and the outer metallic shell extend from a bond pad on the semiconductor substrate.

12. The semiconductor device of claim 11, wherein the inner metallic pillar and the outer metallic shell extend a same distance from the bond pad.

13. The semiconductor device of claim 9, wherein the inner metallic pillar, the outer metallic shell, and the continuous metallic bridging layer include a copper material.

14. The semiconductor device of claim 9, wherein the semiconductor substrate has a top surface, and wherein the continuous metallic bridging layer is parallel to the top surface.

15. The semiconductor device of claim 9, wherein the dielectric liner includes a material with a greater flexibility than a flexibility of a material included by the inner metallic pillar and/or the outer metallic shell.

16. The semiconductor device of claim 9, wherein the dielectric liner includes a polymer material.

17. The semiconductor device of claim 9, wherein the interconnection structure further includes a solder material over the continuous metallic bridging layer.

18. The semiconductor device of claim 17, wherein the interconnection structure further includes a metallic interconnection layer between the solder material and the continuous metallic bridging layer.

19. The semiconductor device of claim 18, wherein the metallic interconnection layer includes a nickel material.

20. A method of manufacturing a semiconductor die interconnection structure, comprising:
preparing a semiconductor die with a bond pad at a top surface;
forming a dielectric layer over the bond pad and the top surface;
removing a portion of the dielectric layer to form an annular dielectric liner over the bond pad;
forming a metallic seed layer over the bond pad, the top surface, and the annular dielectric liner;
forming a patterned photoresist layer over the metallic seed layer with an opening surrounding the annular dielectric liner;
plating a metal into the opening to form an interconnect structure including:
a pillar in a central space of the annular dielectric liner,
a shell surrounding an outer surface of the annular dielectric liner, and
a bridging layer over the pillar, the shell, and the annular dielectric liner;
removing the patterned photoresist layer; and
removing the metallic seed layer from the top surface, and from the bond pad surrounding the interconnect structure.
